(19) United States
(12) Patent Application Publication
(10) Pub. No.: US 2017/0261547 A1
(43) Pub. Date: Sep. 14, 2017

(54) Temperature Forcing System and Method with Conductive Thermal Probes

(71) Applicant: Temptronic Corporation, Mansfield, MA (US)

(72) Inventor: Norbert Elsdoerfer, Mansfield, MA (US)

(73) Assignee: Temptronic Corporation, Mansfield, MA (US)

(21) Appl. No.: 15/437,861

(22) Filed: Feb. 21, 2017

Related U.S. Application Data
(60) Provisional application No. 62/305,263, filed on Mar. 8, 2016.

(51) Int. Cl. G01R 31/28; G01R 1/067

(52) U.S. Cl. CPC G01R 31/2874; G01R 1/067

(57) ABSTRACT

A temperature-controlled fluid forcing system includes a temperature control system generating a stream of flowing temperature-controlled fluid. A heat exchanger includes a thermally conductive housing within which a plurality of walls define a shaped flow space. The stream of temperature-controlled fluid flows through the shaped flow space and is in thermal communication with the housing. A thermally conductive probe is in thermal communication with the exterior of the housing of the heat exchanger, the thermally conductive probe comprising a thermally conductive protrusion in thermal communication with the exterior of the housing of the heat exchanger, such that, when the thermally conductive probe makes contact with a device under test (DUT), heat is conducted to or from DUT.

### RELATED APPLICATIONS

This application claims priority to and benefit of U.S. Provisional Patent Application No. 62/305,263, filed Mar. 8, 2016, the contents of which are incorporated herein by reference in their entirety for all purposes.

### BACKGROUND

1. Technical Field

The present invention generally relates to temperature forcing systems, which provide a stream of fluid at a precisely-controlled temperature and flow rate, and are commonly used in temperature testing of electronic devices, modules and systems, and, in particular, to a temperature forcing system which uses heat flow by conduction instead of convection to apply temperature control of a device under test (DUT) with increased efficiency and spatial precision.

2. Discussion of Related Art

A temperature forcing system is a device which produces a stream of flowing fluid, such as air, nitrogen or other inert gas, at a precisely-controlled temperature and flow rate. Such systems are commonly used in temperature testing of electronic devices, modules and systems. In this application, a stream of temperature-controlled fluid is directed onto the device under test (DUT) to affect the temperature of the DUT. The DUT is then run through a series of performance tests to determine whether the performance of the DUT at various temperatures is acceptable.

These temperature stream testing systems use convection heat transfer to control temperature of the DUT. Oftentimes, it can be desirable to direct the temperature altering mechanism, i.e., stream, precisely, such that only the portion of the DUT actually being tested is affected by the temperature stream. This can result in a reduction in lost temperature control fluid, and, therefore, a more efficient testing system and process.

### SUMMARY

According to one aspect, a temperature-controlled fluid forcing system is provided. The system includes a temperature control system for cooling and/or heating a fluid and generating a stream of flowing temperature-controlled fluid. A conduit directs the stream of flowing temperature-controlled fluid through a first outlet. A heat exchanger receives the stream of temperature-controlled fluid from the first outlet. The heat exchanger comprises: (i) a thermally conductive housing having an interior and an exterior, (ii) an inlet at which the stream of temperature-controlled fluid is received, such that the stream of temperature-controlled fluid is directed into the interior of the housing, (iii) a plurality of walls within the interior of the housing, the plurality of walls defining a shaped flow space within the interior of the housing, the inlet being in communication with the shaped flow space such that the stream of temperature-controlled fluid flows through the shaped flow space and is in thermal communication with the housing, and (iv) a second outlet in communication with the shaped flow space such that the stream of temperature-controlled fluid is exhausted from the interior of the housing through the second outlet after flowing through the shaped flow space;. A thermally conductive probe is disposed in thermal communication with the exterior of the housing of the heat exchanger, the thermally conductive probe comprising a thermally conductive protrusion in thermal communication with the exterior of the housing of the heat exchanger, such that, when the thermally conductive probe makes contact with a device under test (DUT), heat is conducted to or from DUT.

In some exemplary embodiments, when the thermally conductive probe makes contact with the device under test (DUT), temperature of the DUT is controllable.

In some exemplary embodiments, the system further comprises a temperature sensing device for sensing temperature of the thermally conductive probe, the temperature of the thermally conductive probe being used to control temperature of the DUT.

In some exemplary embodiments, the system further comprises a temperature sensing device for sensing temperature of the DUT, such that temperature of the DUT is controllable.

In some exemplary embodiments, the shaped flow space in the interior of the housing of the heat exchanger comprises a serpentine shape.

In some exemplary embodiments, the housing of the heat exchanger comprises a thermally conductive material. The thermally conductive material can comprise metal. The thermally conductive material can comprise aluminum. The thermally conductive material can comprise copper.

In some exemplary embodiments, the thermally conductive probe comprises a thermally conductive material. The thermally conductive material can comprise metal. The thermally conductive material can comprise aluminum. The thermally conductive material can comprise copper.

### BRIEF DESCRIPTION OF THE DRAWINGS

The foregoing and other objects, features and advantages will be apparent from the following, more particular description of the embodiments, as illustrated in the accompanying figures, wherein like reference characters generally refer to identical or structurally and/or functionally similar parts throughout the different views. The figures are not necessarily to scale, emphasis instead being placed upon illustrating the principles of the embodiments.

FIG. 1 includes a schematic perspective view of a temperature-controlled fluid processing system, for example, a temperature forcing system, e.g., air forcing system, to which the present disclosure is applicable.

FIG. 2 includes a schematic perspective view of another embodiment of a temperature-controlled fluid processing system, for example, a temperature forcing system, e.g., an air forcing system, to which the present disclosure is applicable.

FIG. 3 includes a detailed schematic diagram of a portion of temperature forcing system of FIG. 1, according to another exemplary embodiment.

FIG. 4 includes a schematic diagram of a temperature forcing system, using a conductive temperature probe for controlling temperature of a DUT, according to exemplary embodiments.

FIG. 5 includes a schematic diagram of another temperature forcing system, using a conductive temperature probe for controlling temperature of a DUT, according to exemplary embodiments.

FIG. 6 includes a schematic perspective view of a heat exchanger used in a temperature forcing system, according to some exemplary embodiments.

FIG. 7 includes a schematic cross-sectional view of the heat exchanger of FIG. 6, taken along line 7-7 of FIG. 6, according to exemplary embodiments.

FIG. 8 includes a schematic cross-sectional view of the heat exchanger of FIG. 6, taken along line 8-8 of FIG. 7, according to exemplary embodiments.

FIG. 9A includes a schematic perspective view of a contact probe, according to exemplary embodiments.

FIG. 9B includes a bottom view of the contact probe of FIG. 9A, illustrating the configuration of a contact protrusion portion of the contact probe, according to some exemplary embodiments.

FIG. 10A includes a schematic perspective view of another contact probe, according to exemplary embodiments.

FIG. 10B includes a bottom view of the contact probe of FIG. 10A, illustrating the configuration of a contact protrusion portion of the contact probe, according to some exemplary embodiments.

FIG. 11A includes a schematic perspective view of another contact probe, according to exemplary embodiments.

FIG. 11B includes a bottom view of the contact probe of FIG. 11A, illustrating the configuration of a contact protrusion portion of the contact probe, according to some exemplary embodiments.

### DETAILED DESCRIPTION

In the description that follows, features that are described and/or illustrated with respect to one embodiment may be used in the same way or in a similar way in one or more other embodiments and/or in combination with or instead of the features of the other embodiments. Description will now be made in detail of exemplary embodiments, one or more of which are illustrated in the drawings. Each embodiment is provided to illustrate the invention, and is not meant as a limitation of the invention. For example, features illustrated or described as part of one embodiment can be used in another embodiment to yield a further embodiment. It is intended that the present description include such modifications and variations as come within the scope and spirit of the invention.

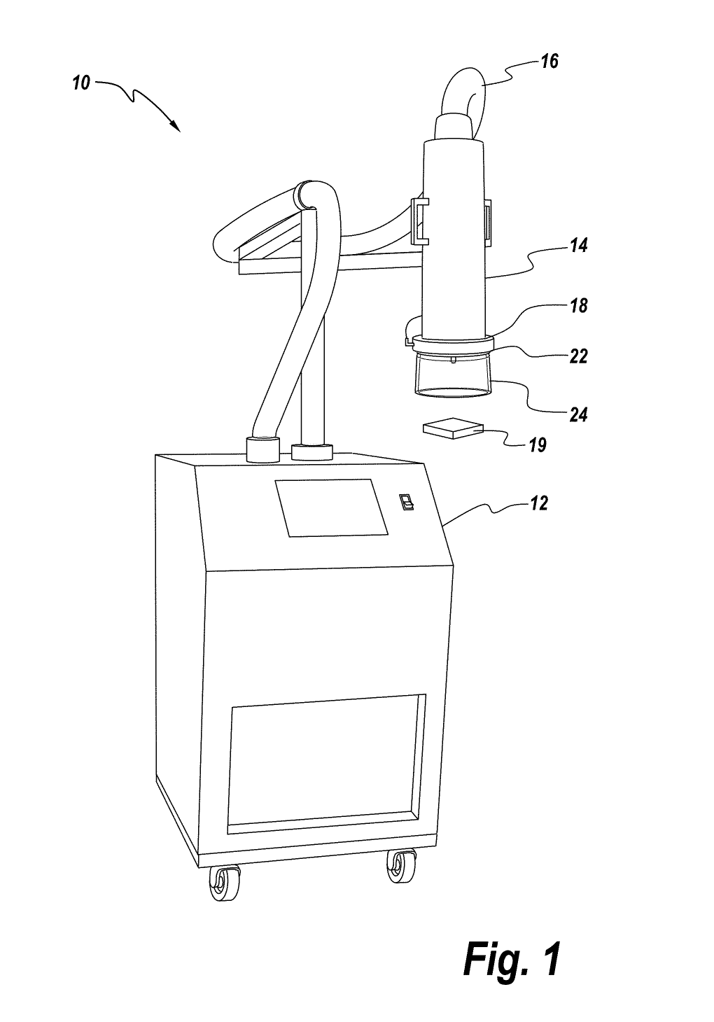

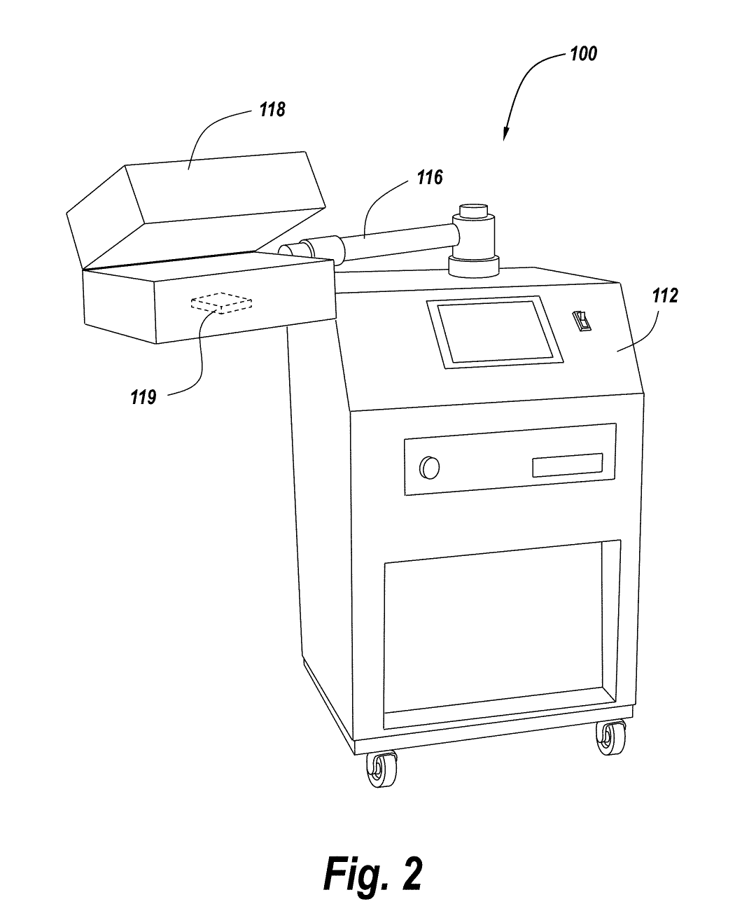

FIG. 1 includes a schematic perspective view of a temperature-controlled fluid processing system, for example, a temperature forcing system, e.g., air forcing system 10, to which the present disclosure is applicable. FIG. 2 includes a schematic perspective view of another embodiment of a temperature-controlled fluid processing system, for example, a temperature forcing system, e.g., air forcing system 100, to which the present disclosure is applicable. Temperature forcing systems 10, 100 to which the present disclosure is directed can be used to produce a fluid such as air, nitrogen, or other inert gas with a precisely controlled temperature and flow rate, and can direct a stream of that fluid into a particular region, such as, for example, onto a device under test (DUT) 19, 119, to control the temperature of the DUT 19, 119. DUT 19, 119 can be an integrated circuit (IC), which can be contained within its IC package. Alternatively, DUT 19, 119 can be a semiconductor wafer with multiple IC dies integrated therein, or it can be a printed circuit board (PCB) with multiple ICs installed thereon. According to some exemplary embodiments, the temperature-controlled forcing system 10, 100 may comprise a THERMOSTREAM® Air Forcing System, as manufactured and sold by inTEST Thermal Solutions Corporation of Mansfield, Mass., or other similar system.

Temperature forcing systems 10, 100 may include a chiller/controller unit 12, 112, which includes a refrigeration system for generating a stream of dry, cold gas, e.g., air, nitrogen or other fluid. The chilled fluid may be directed into a fluid conveyor, such as a tube and hose system 16, 116 which in system 10 directs the air into a head unit 14 and in system 100 directs the air into an insulated “clamshell” box appliance 118, in which DUT 119 is located, such that temperature of DUT 119 can be controlled. Head unit 14 may include a heater for heating the chilled fluid, such that temperature of the fluid can be precisely controlled. The temperature-controlled fluid may exit head 14 through an outlet 18. In some exemplary embodiments, a “T-Cap” thermal cap accessory 22 having a shroud 24 is commonly attached at outlet 18. Shroud 24 can be used to at least partially enclose or cover DUT 19 to provide a contained temperature-controlled environment in which temperature of DUT 19 is controlled. In system 100 of FIG. 2, clamshell appliance 118 provides a contained temperature-controlled environment in which temperature of DUT 19 is controlled.

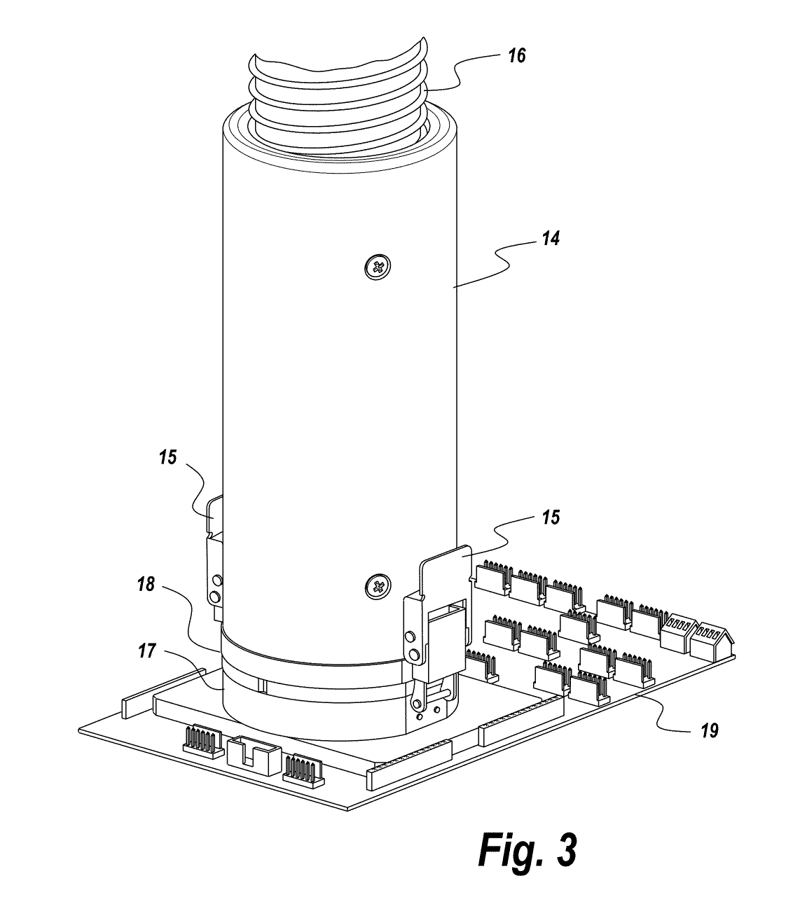

FIG. 3 includes a detailed schematic diagram of a portion of temperature forcing system 10 of FIG. 1, according to another exemplary embodiment. In this embodiment, head unit 14 is connected by claims 15 at outlet 18 to a ring 17, which mounts over and at least partially encloses DUT 19. In this exemplary illustration, DUT 19 is illustrated as a PCB with multiple electronic devices mounted thereon.

Thus, according to temperature forcing systems 10, 100 illustrated in FIGS. 1-3, as described above, temperature control is achieved by convection via the flow of the temperature-controlled fluid onto or in close proximity to DUT 19, 119. According to exemplary embodiments, temperature forcing systems 10, 100 can be modified such that heat transfer by conduction is used to force DUTs 19, 119 to a desired test temperature. To achieve this conversion from heat transfer by convection to heat transfer by conduction, according to exemplary embodiments, the output fluid flow from temperature forcing systems 10, 100 is forced into a high-efficiency heat exchanger, which can be positioned in contact with DUT 19, 119. The heat exchanger is maintained in contact with DUT 19, 119 such that the heat transfer is accomplished using a thermal conduction path. One benefit of conductive temperature control of DUT 19, 119 over convective temperature control is that, with the conductive temperature control of the present disclosure, only the device to be tested, i.e., DUT 19, 119, is affected thermally. Other elements, such as, for example, adjacent components and/or the load board itself, can remain thermally isolated while temperature of DUT 19, 119 is affected. This results in substantially reduced loss or waste of temperature control fluid, which in turn produces a more efficient test system and process.

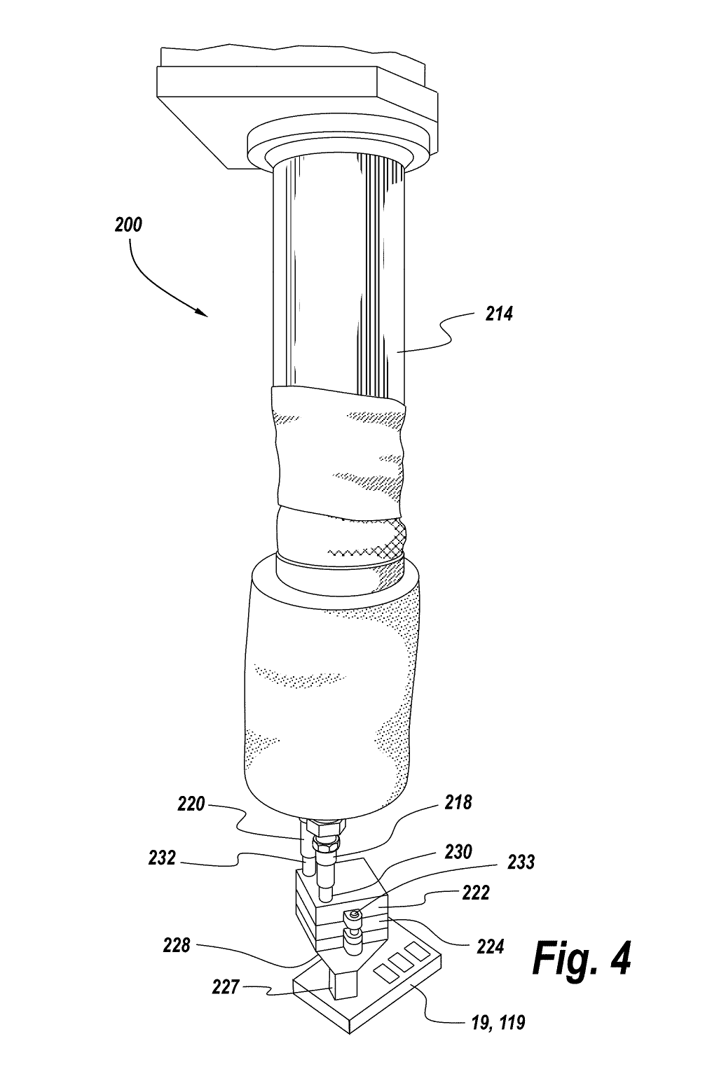

FIG. 4 includes a schematic diagram of a temperature forcing system 200, using a conductive temperature probe for controlling temperature of a DUT, according to exemplary embodiments. Referring to FIG. 4, a portion of system 200 is illustrated to facilitate detailed description. The remainder of system 200 not shown in the figure is the same as that portion of system 10 illustrated in FIG. 1. System 200 includes head unit 214, analogous to head unit 14 of system 10. An outlet pipe structure 218 is coupled to the output of head unit 214 to capture and carry the temperature-controlled fluid output by system 200 for temperature control. Outlet pipe structure 218 transports the temperature-controlled fluid into an inlet 230 of high-efficiency heat exchanger 222, which circulates the fluid internally and outputs the fluid at outlet 232, which is connected to exhaust pipe 220. The temperature-controlled fluid circulating in the interior of heat exchanger 222 transfers heat to/from the thermally conductive body of heat exchanger 222, which contacts an optional thermally conductive thermocouple mounting plate 224. Thermocouple mounting plate 224 can be used as a means for mounting and connecting a thermocouple in proximity to or in contact with heat exchanger 222 to monitor its temperature, if desired. This can provide an optional temperature parameter input, which can be used, if desired, in the temperature control function of system 200.

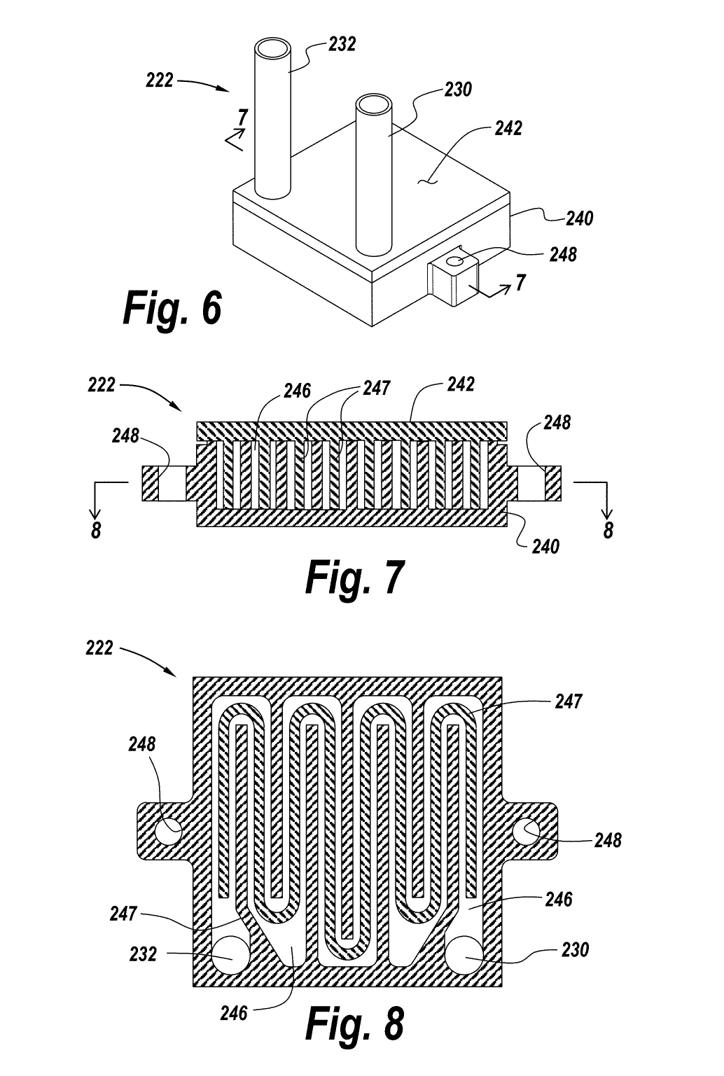

When present, thermally conductive thermocouple mounting plate 224 is thermally connected to a thermally conductive DUT contact probe 228, which is mounted on the bottom surface of thermally conductive thermocouple mounting plate 224. If thermally conductive thermocouple mounting plate 224 is not present, then thermally conductive DUT contact probe 228 is mounted to the bottom surface of heat exchanger 222. In either configuration, heat transfer to/from DUT 19, 119 is effected conductively by contact of a contact protrusion portion 227 of thermally conductive DUT contact probe 228 with DUT 19, 119. It is noted that, in some exemplary embodiments, heat exchanger 222, thermocouple mounting plate 224, and DUT contact probe 228 can be held together by one or more pins 233 through mounting holes 248 in mounting bosses 235 (see FIGS. 6-8). Other means of attachment can be used, such as screws, nuts and bolts, etc.

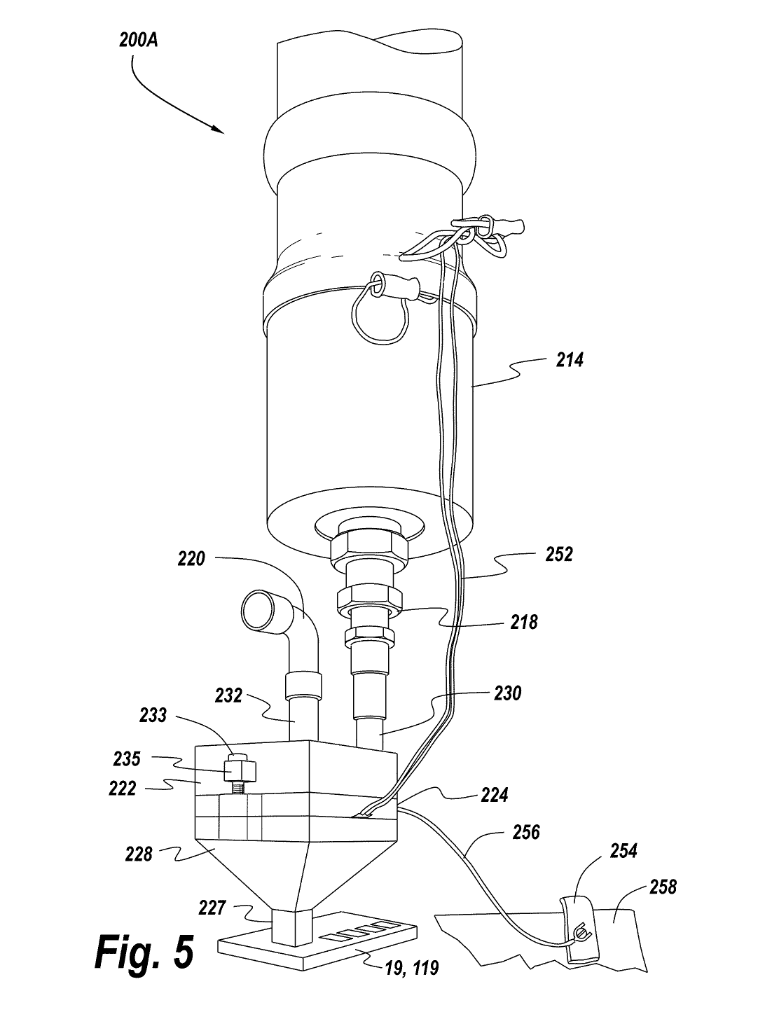

FIG. 5 includes a schematic diagram of a temperature forcing system 200A, using a conductive temperature probe for controlling temperature of a DUT, according to exemplary embodiments. Referring to FIG. 5, a portion of system 200A is illustrated to facilitate detailed description. The remainder of system 200A not shown in the figure is the same as that portion of system 10 illustrated in FIG. 1. System 200A of FIG. 5 is similar to system 200 of FIG. 4, except that FIG. 5 illustrates system 200A making use of one or more thermocouples to monitor one or more respective temperature parameters which optionally can be used in the temperature control implemented by system 200A. Referring to FIG. 5, system 200A includes head unit 214, analogous to head unit 14 of system 10. Outlet pipe structure 218 is coupled to the output of head unit 214 to capture and carry the temperature-controlled fluid output by system 200 for temperature control. Outlet pipe structure 218 transports the temperature-controlled fluid into an inlet 230 of high-efficiency heat exchanger 222, which circulates the fluid internally and outputs the fluid at outlet 232, which is connected to exhaust pipe 220. The temperature-controlled fluid circulating in the interior of heat exchanger 222 transfers heat to/from the thermally conductive body of heat exchanger 222, which contacts an optional thermally conductive thermocouple mounting plate 224. Thermocouple mounting plate 224 can be used as a means for mounting and connecting a thermocouple (not shown) in proximity to or in contact with heat exchanger 222 to monitor its temperature, if desired. An optional second thermocouple 254 can be mounted to and monitor temperature of a portion 258 of system 200A in proximity to DUT 19, 119. The thermocouples are wired via wires 256 and 252, via head 214, to system controller in chiller/controller unit 12, 112. This can provide one or more optional temperature parameter inputs, which can be used, if desired, in the temperature control function of system 200A.

When present, thermally conductive thermocouple mounting plate 224 is thermally connected to a thermally conductive DUT contact probe 228, which is mounted on the bottom surface of thermally conductive thermocouple mounting plate 224. If thermally conductive thermocouple mounting plate 224 is not present, then thermally conductive DUT contact probe 228 is mounted to the bottom surface of heat exchanger 222. In either configuration, heat transfer to/from DUT 19, 119 is effected conductively by contact of a contact protrusion portion 227 of thermally conductive DUT contact probe 228 with DUT 19, 119. It is noted that, in some exemplary embodiments, heat exchanger 222, thermocouple mounting plate 224, and DUT contact probe 228 can be held together by one or more pins 233 through mounting holes 248 in mounting bosses 235 (see FIGS. 6-8). Other means of attachment can be used, such as screws, nuts and bolts, etc.

FIG. 6 includes a schematic perspective view of heat exchanger 222, according to some exemplary embodiments. FIG. 7 includes a schematic cross-sectional view of heat exchanger 222, taken along line 7-7 of FIG. 6, according to some exemplary embodiments. FIG. 8 includes a schematic cross-sectional view of heat exchanger 222, taken along line 8-8 of FIG. 7, according to some exemplary embodiments. Referring to FIGS. 6-8, heat exchanger 222 includes a thermally conductive housing portion 240 fixedly attached to a thermally conductive cover portion 242. Housing portion 240 and cover portion 242 can be made of similar or like thermally conductive materials such as metals, which can be, for example, aluminum, copper, or other thermally conductive material, and can be sealed together by some thermally conductive means, such as welding, brazing, or other process. As noted above, temperature-controlled fluid from head unit 214 of system 200, 200A enters heat exchanger 222 through inlet 230 and circulates through the interior of heat exchanger 222 via a serpentine pattern of void space 246 defined and contained by interior wall structure 247. The fluid then exits the interior of heat exchanger 222 via outlet 232.

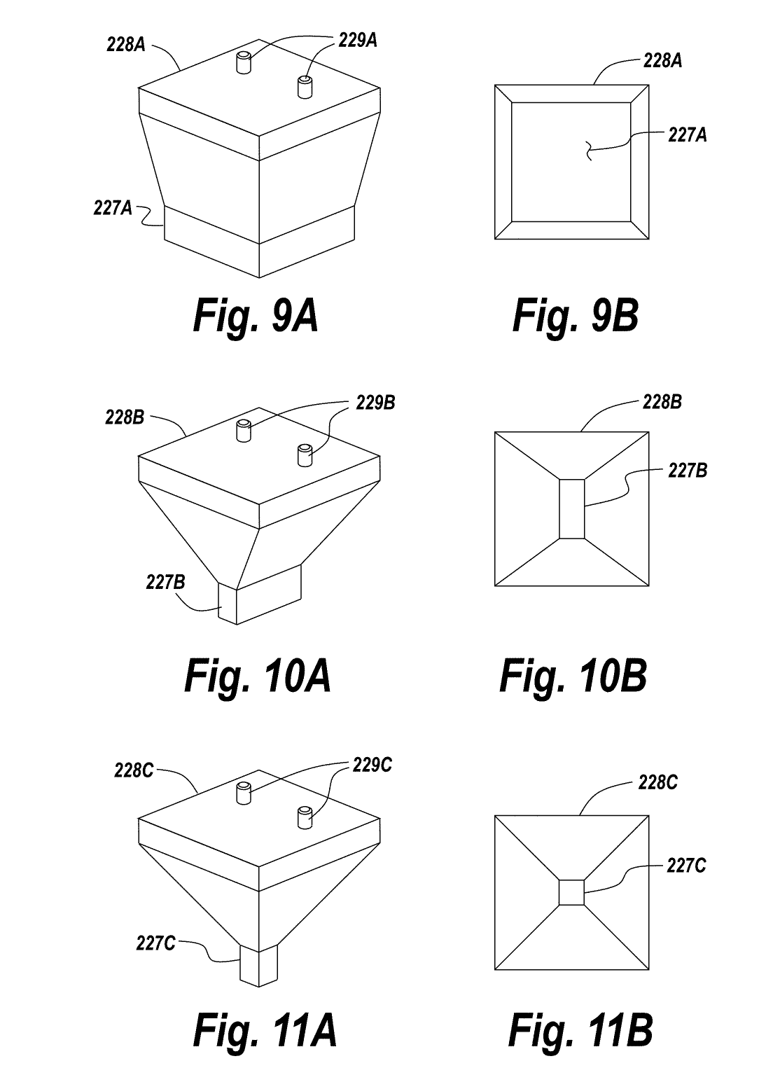

Contact probe 228 can have a size and shape of multiple possible sizes and shapes, depending on the particular needs of the particular application. Also, contact protrusion portion 227 of each contact probe 228 can be sized depending on the application, as well as the size constraints of the DUT 19, 119, or region of DUT 19, 119 at which temperature effect is to be applied. FIG. 9A includes a schematic perspective view of a contact probe 228A, according to exemplary embodiments. FIG. 9B includes a bottom view of contact probe 228A of FIG. 9A, illustrating the configuration of contact protrusion portion 227A of contact probe 228A, according to some exemplary embodiments. FIG. 10A includes a schematic perspective view of a contact probe 228B, according to exemplary embodiments. FIG. 10B includes a bottom view of contact probe 228B of FIG. 10A, illustrating the configuration of contact protrusion portion 227B of contact probe 228B, according to some exemplary embodiments. FIG. 11A includes a schematic perspective view of a contact probe 228C, according to exemplary embodiments. FIG. 11B includes a bottom view of contact probe 228C of FIG. 11A, illustrating the configuration of contact protrusion portion 227C of contact probe 228C, according to some exemplary embodiments. It will be understood that FIGS. 9A-11B are not exhaustive of all of the possible configurations of contact probes 228 and associated contact protrusion portions 227. Rather, they illustrate that the configurations provide a wide range of variations depending on the particular application. Any number of configurations is possible.

Referring to FIGS. 9A, 10A, 11A, contact probes 228A, 228B, 228C include attachment/location pins 229A, 229B, 229C, respectively. These pins mate with holes on the undersides of heat exchanger 222 or thermocouple mounting plate 224 to locate contact probes 228A, 228B, 228C properly and/or to fixedly mount contact probes 228A, 228B, 228C in thermally conductive contact with heat exchanger 222 or thermocouple mounting plate 224. Contact probe 228 and contact protrusion portions 227 can be made of similar or like thermally conductive materials such as metals, which can be, for example, aluminum, copper, or other thermally conductive material.

While the present inventive concept has been particularly shown and described with reference to exemplary embodiments thereof, it will be understood by those of ordinary skill in the art that various changes in form and details may be made therein without departing from the spirit and scope of the present inventive concept as defined by the following claims.

1. A temperature-controlled fluid forcing system, comprising:
a temperature control system for cooling and/or heating a fluid and generating a stream of flowing temperature-controlled fluid;
a conduit for directing the stream of flowing temperature-controlled fluid through a first outlet;
a heat exchanger for receiving the stream of temperature-controlled fluid from the first outlet, the heat exchanger comprising:
a thermally conductive housing having an interior and an exterior,
an inlet at which the stream of temperature-controlled fluid is received, such that the stream of temperature-controlled fluid is directed into the interior of the housing,
a plurality of walls within the interior of the housing, the plurality of walls defining a shaped flow space within the interior of the housing, the inlet being in communication with the shaped flow space such that the stream of temperature-controlled fluid flows through the shaped flow space and is in thermal communication with the housing, and
a second outlet in communication with the shaped flow space such that the stream of temperature-controlled fluid is exhausted from the interior of the housing through the second outlet after flowing through the shaped flow space; and
a thermally conductive probe in thermal communication with the exterior of the housing of the heat exchanger, the thermally conductive probe comprising a thermally conductive protrusion in thermal communication with the exterior of the housing of the heat exchanger, such that, when the thermally conductive probe makes contact with a device under test (DUT), heat is conducted to or from DUT.

2. The system of claim 1, wherein, when the thermally conductive probe makes contact with the device under test (DUT), temperature of the DUT is controllable.

3. The system of claim 1, further comprising a temperature sensing device for sensing temperature of the thermally conductive probe, the temperature of the thermally conductive probe being used to control temperature of the DUT.

4. The system of claim 1, further comprising a temperature sensing device for sensing temperature of the DUT, such that temperature of the DUT is controllable.

5. The system of claim 1, wherein the shaped flow space in the interior of the housing of the heat exchanger comprises a serpentine shape.

6. The system of claim 1, wherein the housing of the heat exchanger comprises a thermally conductive material.

7. The system of claim 6, wherein the thermally conductive material comprises metal.

8. The system of claim 6, wherein the thermally conductive material comprises aluminum.

9. The system of claim 6, wherein the thermally conductive material comprises copper.

10. The system of claim 1, wherein the thermally conductive probe comprises a thermally conductive material.

11. The system of claim 10, wherein the thermally conductive material comprises metal.

12. The system of claim 10, wherein the thermally conductive material comprises aluminum.

13. The system of claim 10, wherein the thermally conductive material comprises copper.
